(19) United States
(12) Patent Application Publication
(10) Pub. No.: US 2017/0314959 A1
(43) Pub. Date: Nov. 2, 2017

(54) Center Pedestal Display

(71) Applicant: Bell Helicopter Textron Inc., Fort Worth, TX (US)

(72) Inventors: Jeremy R. Chavez, Colleyville, TX (US); Steven W. Kihara, North Richland Hills, TX (US); Jeffery W. Erwin, Chico, TX (US)

(73) Assignee: Bell Helicopter Textron Inc., Fort Worth, TX (US)

(21) Appl. No.: 15/497,113

(22) Filed: Apr. 25, 2017

Related U.S. Application Data
(60) Provisional application No. 62/328,582, filed on Apr. 27, 2016.

(51) Int. Cl. G01C 23/00; G06F 3/01; B64C 13/00

(52) U.S. Cl. CPC G01C 23/00; B64C 13/00; G06F 3/01; H05K 5/00

(57) ABSTRACT

An aircraft system interface has a center pedestal and a touchscreen display carried by the center pedestal. The interface has one or more programs including instructions for displaying a virtual input device, instructions for detecting movement of an object on or near the touchscreen display, and instructions for rotating the virtual input device displayed on the touchscreen display in response to detecting the movement.

### CROSS-REFERENCE TO RELATED APPLICATIONS

This patent application claims the benefit of the filing date of the U.S. Provisional Patent Application Ser. No. 62/328,582, filed on 27 Apr. 2016 and entitled “Center Pedestal Display,” the entire content of which is expressly incorporated by reference.

### BACKGROUND

The cockpits of modern aircraft have evolved from exclusive use of mechanical and electromechanical gauges and switches to use of electronic displays and switches for primary flight instruments and control of aircraft systems. These displays include multi-function displays (MFDs), which typically use line-address and bezel keys arrayed around the screen to access modes for data entry or activate functions.

### BRIEF DESCRIPTION OF THE DRAWINGS

FIG. 1 is an oblique see-through view of a forward portion of an aircraft.

FIG. 2 is a rear view of an instrument panel and center pedestal assembly of the aircraft of FIG. 1.

FIG. 3 is a normal view of a central display unit of the aircraft of FIG. 1.

FIG. 4 is a normal view of a keyboard of the aircraft of FIG. 1.

FIG. 5 is an oblique see-through view of a forward portion of an aircraft.

FIG. 6 is a rear view of an instrument panel and center pedestal assembly of the aircraft of FIG. 5, the center pedestal being configured according to this disclosure.

FIG. 7 is a normal view of a first embodiment of a graphical display mode of the center pedestal of FIG. 6 and according to this disclosure.

FIG. 8 is a normal view of another embodiment of a graphical display mode of the center pedestal of FIG. 6 and according to this disclosure.

FIG. 9 is a normal view of another embodiment of a graphical display mode of the center pedestal of FIG. 6 and according to this disclosure.

FIG. 10 is a normal view of another embodiment of a graphical display mode of the center pedestal of FIG. 6 and according to this disclosure.

FIG. 11 is a normal view of another embodiment of a graphical display mode of the center pedestal of FIG. 6 and according to this disclosure.

FIG. 12 is a normal view of another embodiment of a graphical display mode of the center pedestal of FIG. 6 and according to this disclosure.

FIG. 13 is a simplified representation of a general-purpose processor (e.g. electronic controller or computer) system suitable for implementing the embodiments of this disclosure.

### DETAILED DESCRIPTION

In this disclosure, reference may be made to the spatial relationships between various components and to the spatial orientation of various aspects of components as the devices are depicted in the attached drawings. However, as will be recognized by those skilled in the art after a complete reading of the present disclosure, the devices, members, apparatuses, etc. described herein may be positioned in any desired orientation. Thus, the use of terms such as “above,” “below,” “upper,” “lower,” or other like terms to describe a spatial relationship between various components or to describe the spatial orientation of aspects of such components should be understood to describe a relative relationship between the components or a spatial orientation of aspects of such components, respectively, as the device described herein may be oriented in any desired direction.

Aircraft system interfaces, such as those for tuning radio frequencies, accessing system diagnostic displays, inputting navigation information, accessing the flight director, etc., have typically been physical knobs, buttons, and switches affixed to the airframe on a forward instrument panel or center pedestal and oriented parallel to the aircraft centerline. Touchscreens are becoming more commonplace in aircraft, but these are typically constrained to being small screens that are also oriented parallel to the aircraft centerline.

Most flight-crew seats are installed in a fixed orientation relative to an aircraft centerline so that the crewmember is facing forward, and this means that system-interface switches, input devices, and displays are oriented parallel to the flight crew. Especially for the interfaces on the center pedestal, this parallel orientation results in the actual or perceived need of the crewmember to rotate the head, bend the neck, bend the torso, or use a combination of these to interact with the interfaces. Crewmembers may experience negative effects ranging from temporary discomfort during flight to permanent physical damage due to occasionally maintaining these contorted positions during thousands of flight hours. In addition, another problem encountered with the use of parallel-to-centerline pedestal interfaces is the colliding of the helmets of crewmembers, which is referred to as “head knocking.” This can occur when a crewmember on one side of the pedestal is interacting with a pedestal-mounted interface and the crewmember on the other side of the pedestal leans in to view the activity, which may be done to, for example, double-check an input value, read a display, or satisfy curiosity.

Replacing traditional pedestal interfaces with a full touchscreen devoid of physical switches, knobs, or keys allows for graphically representing interfaces, and instructions in the software programs can provide for selective rotation of the graphical representations of virtual input keys and switches and related information to an orientation that is more ergonomic for the flight crew. These interfaces are preferably aligned to approximately perpendicular with the head and upper torso as the crewmember naturally turns to interact with the interfaces on the pedestal.

Additionally, the pedestal touchscreen has the ability to provide dual split-screen information for simultaneous access for both crewmembers, with full-screen display for either to access any available configurations.

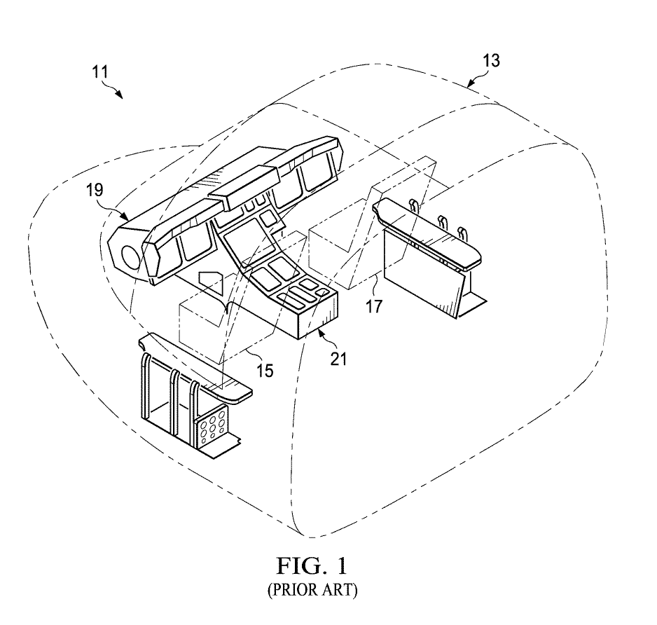

FIG. 1 illustrates the forward portion of an aircraft 11, cockpit 13 being located in the forward portion. Cockpit 13 is the flight deck and the location of primary controls for aircraft systems, and two crewmembers sit in a side-by-side arrangement in seats 15, 17. A pilot-in-command is typically located in left seat 15 for fixed-wing aircraft and right seat 17 for rotary-wing aircraft, and a copilot or instructor pilot is typically located in right seat 17 for fixed-wing aircraft and left seat 15 for rotary-wing aircraft. Aircraft 11 is shown equipped with prior-art instrument panel 19 and prior-art center pedestal 21.

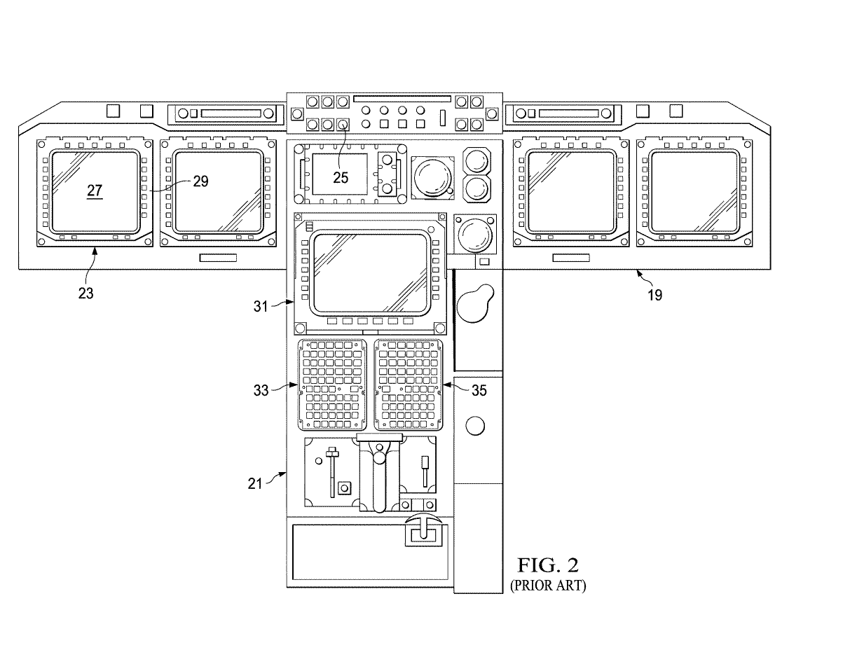

FIGS. 2 through 4 illustrate panel 19, pedestal 21, and components thereof. Panel 19 comprises a pair of MFDs 23 located in front of each crewmember station, as well as various switch panels 25 located across an upper portion of panel 19. MFDs 23 have an LED screen 27 surrounded by function keys 29. Pedestal 21 comprises a central display unit (CDU) 31, a pair of adjacent CDU keyboards 33, 35 (one for each crewmember), and various switches and gauges.

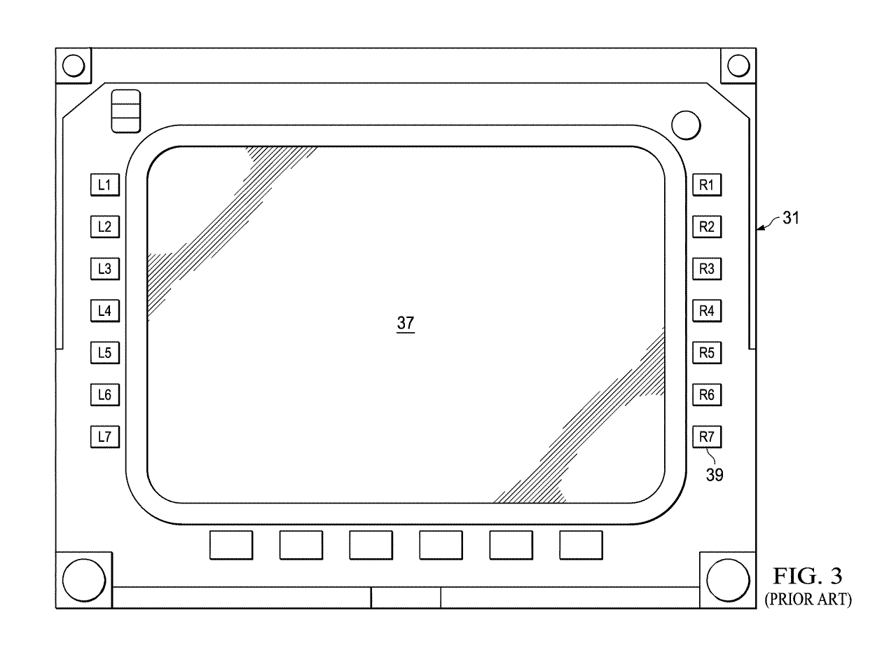

Referring to FIG. 3, CDU 31, like MFDs 23, has an LED screen 37 surrounded by keys 39, which are typically line-address or other bezel keys for operating and interfacing with CDU 31. Screen 37 is in electronic communication with a general-purpose processor system used to generate messages, interactive text, and other graphical representations for display on CDU 31, allowing crewmembers to interface with and control various aircraft systems, as described above.

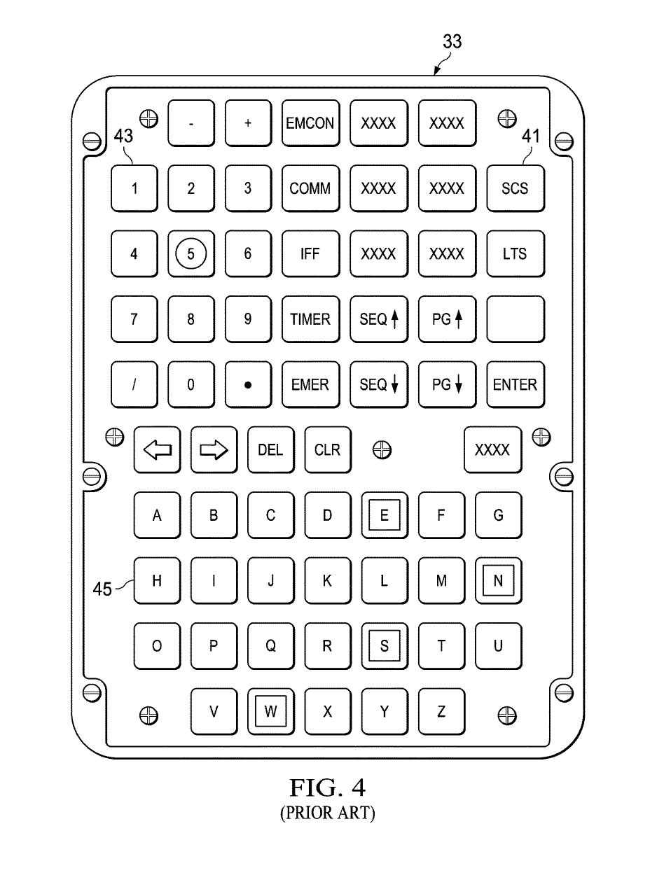

Referring to FIG. 4, CDU keyboard 33 comprises a variety of function keys 41, number pad keys 43, and alphabet keys 45, keyboard 35 having a similar configuration and function to that of keyboard 33. Keys 41, 43, 45 are used by crewmembers to interact with CDU 31, such as for inputting data or making selections in response to text or other representations displayed on screen 37 of CDU 31. For example, a crewmember may press a key 39 on CDU 31, which causes to be displayed on screen 37 text related to a particular aircraft system and mode of input. One crewmember or the other may then use keyboard 33 or 35 to enter data or make a selection from options available in that mode.

As clearly visible in FIG. 2, CDU 31 and keyboards 33, 35 are oriented as parallel to the centerline of aircraft 11, encouraging or requiring crewmembers to maintain awkward positions to interact with keyboards 33, 35, resulting in the negative physical effects mentioned above.

In order to eliminate or reduce the actual or perceived need to lean toward the center pedestal, aircraft 11 may alternatively be equipped with full touchscreen system interfaces according to this disclosure and providing the capability of selective rotation of the displayed graphical elements toward alignment with the crewmember using the interface. In addition, system interfaces according to this disclosure may provide the capability of selective translation of the displayed graphical elements on the touchscreen or between multiple touchscreens.

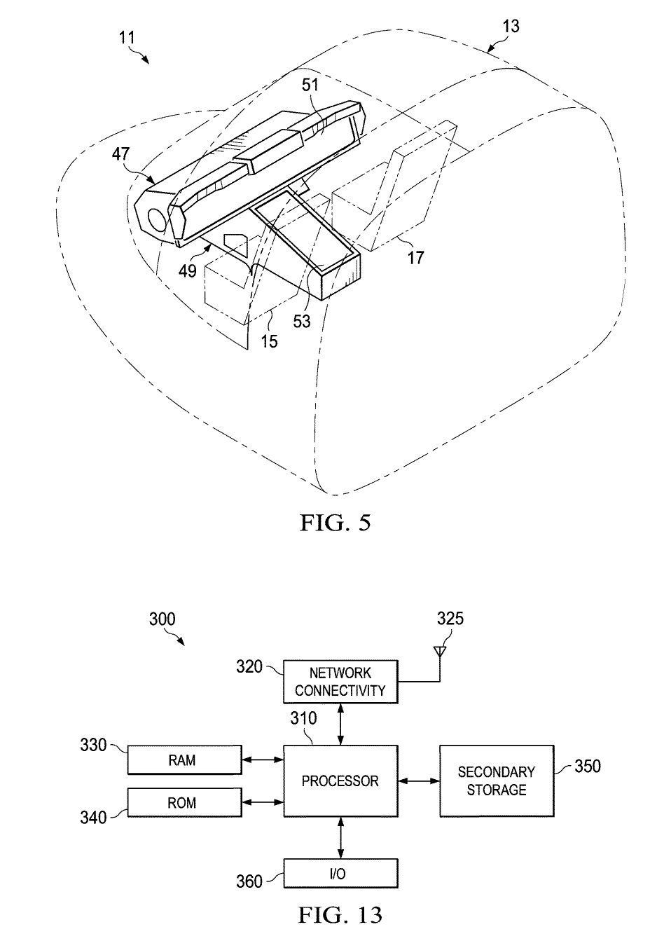

FIG. 5 illustrates the forward portion of aircraft 11, with instrument panel 47 extending across the width of cockpit 13, and center pedestal 49 extending rearward from beneath panel 47 and generally along and parallel to the centerline of aircraft 11. Panel 47 has a touchscreen interface 51 that preferably extends for the entire width of panel 47. Interface 51 is discussed herein as a unitary device, though interface 51 may be constructed of multiple individually replaceable panels. As with panel 19 described above, each crewmember has a portion of panel 47 located in front of one of seats 15, 17, allowing the crewmember to interact with the portion of interface 51 located directly forward of the crewmember. Pedestal 49 is located between seats 15, 17, and pedestal 49 has a touchscreen interface 53 that preferably extends across substantially all of the upward facing portion of pedestal 49. As with panel 19 and 21, described above, touchscreen interfaces 51, 53 are positioned to be within reach of the crewmembers for each crewmember's respective portion of interfaces 51, 53.

FIG. 6 shows panel 47 and pedestal 49 in isolation for ease of viewing. As described above, touchscreen interface 51 preferably extends for the full width of panel 47. Touchscreen interface 53 is located directly below and generally adjacent interface 51, which can provide for an apparent seamless transition between interfaces 51, 53. Instrument panel 47 may optionally comprise physical switches and displays, such as those shown at 55, for various functions. Interfaces 51, 53 are in electronic communication with a general purpose processor system that generates graphical representations for display on interfaces 51, 53 and receives input from crewmembers touching interfaces 51, 53.

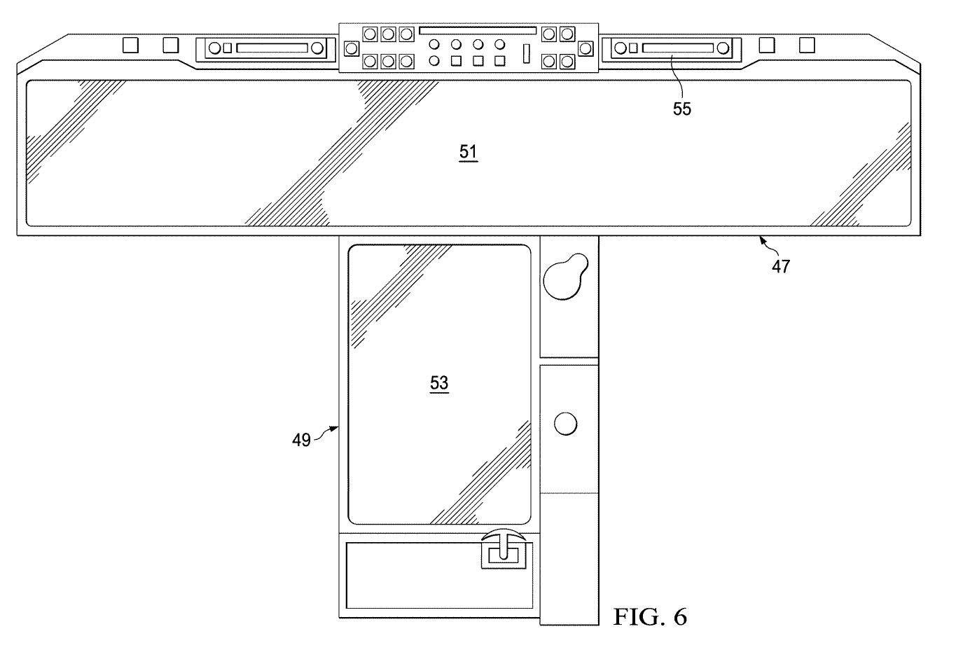

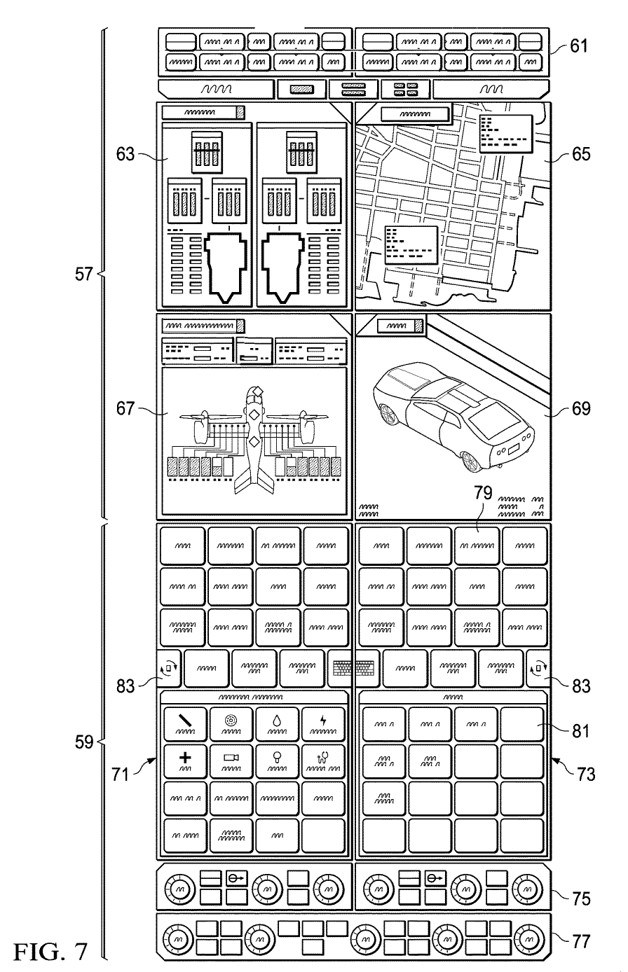

FIG. 7 through 12 illustrate embodiments of graphical display modes for use with touchscreen interfaces 51, 53. In each example embodiment, two sections of graphical displays are shown, with a panel display 57 shown above a pedestal display 59. In the embodiments shown, each panel display 57 is presented to the crewmembers on a central portion of touchscreen interface 51 of panel 47, whereas each pedestal display 59 is presented to the crewmembers on the whole of touchscreen interface 53 of pedestal 49. Though panel display 57 is shown as identical for each embodiment, display 57 can be configured to represent other information, preferably as selected by the crewmembers.

FIG. 7 illustrates an embodiment of a graphical display mode for use with interfaces 51, 53. Panel display 57 is shown representing information related to systems of aircraft 11 in areas 61, 63, 65, 67, 69, and these areas may be configured as shown or in alternative configurations. As shown, areas 61, 63, 67 represent the status of systems of aircraft 11, whereas areas 65, 69 represent data illustrating environments external to aircraft 11. Panel display 57 is the primary means through which crewmembers visually monitor aircraft systems and see results from input at pedestal display 59.

Pedestal display 59 is the primary means through which crewmembers directly interface with the systems of aircraft 11. As shown in FIG. 7, display 59 includes graphical representations of virtual input devices, such as arrays of virtual keys and knobs, and these are configured in an orientation parallel to the centerline of aircraft 11 as typically found for physical interfaces of prior-art pedestals. In normal use, display 59 is preferably separated into a left input section 71 and a right input section 73, as well as additional display/input areas 75, 77 located below section 71, 73. Sections 71, 73 comprise graphical representations of virtual function or input keys 79, as well as representations of empty virtual key locations 81. Providing a split pedestal display 59 allows the crewmembers to see and configure their respective sections 71, 73, which may be identical or similar, or each section 71, 73 may have a configuration specific to each crewmember and based on assigned tasks.

In the preferred embodiments, only virtual keys applicable to the selected mode(s) appear, allowing for decluttering of pedestal display 59. For example, if inputting only numbers, only a number pad appears for that crewmember. This is applicable, for example, when inputting a radio frequency or decimal GPS coordinates. However, inputting, for example, a military grid reference system (MGRS) coordinate or other alphanumeric data would preferably show only the keys necessary for that type of input.

The use of a touchscreen on pedestal interface 53 for presenting pedestal display 59 eliminates the requirement for physical input devices, such as physical keyboards, that are affixed to the pedestal and aligned with the centerline of aircraft 11. This allows for any virtual input device, such as, for example, virtual keys, keyboards, number pads and knobs, to be rotated to a more ergonomic orientation relative to the crewmember interfacing with the virtual input device. This allows a crewmember to more easily work on assigned tasks and may reduce the urge for the other crewmember to twist or lean toward the pedestal to watch data input. In this way, safety may be enhanced by, for example, having the pilot focus on operating the aircraft, and the other crewmember can focus on other tasks, including, for example, operating weapon or reconnaissance systems or acting as mission commander. The system can be configured to use various methods to identify individual crewmembers, thereby allowing for user-associated profiles to provide tailored display configurations, including choices of graphical elements, positions, and angles.

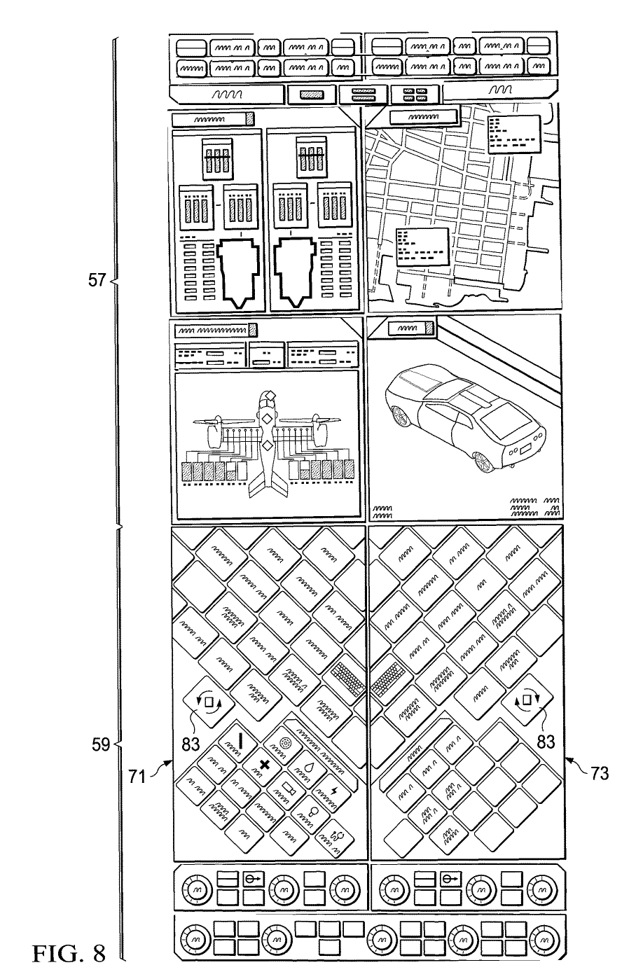

FIG. 8 through 12 illustrate additional embodiments of a graphical display mode for use with interfaces 51, 53. In these figures, panel display 57 is configured as described above for FIG. 7, and pedestal display 59 comprises one or more virtual input devices rotated to a user-selectable angle using a virtual rotate button 83. The amount of rotation may be a preselected angle, or the amount of rotation may correspond to detected motion of an object, such as a finger of a crewmember or a stylus, on or near display 59. In addition to rotation, the use of touchscreens allows for pinch and zoom motions to alter the graphical representations depicted on display 59, and display 59 may provide the ability to use a motion to slide graphical elements to preferred positions or for the use of the other crewmember.

Due to space limitations encountered due to rotation, virtual keys will preferably be prioritized as needed to populate the available space, with secondary keys moving to an off-screen page. It is preferred that main keys will remain on the screen and may stay in a selected orientation despite being rotated.

FIG. 8 illustrates another embodiment of a graphical display mode for use with interfaces 51, 53. In this display mode, both sections 71, 73 have graphical representation of virtual input devices, similar to those shown in FIG. 7, but the virtual input devices are rotated 45 degrees relative to the centerline of aircraft 11. This rotated representation allows each crewmember to view and interact with the virtual input devices on the crewmember's respective section 71, 73 with reduced need to rotate or bend the torso.

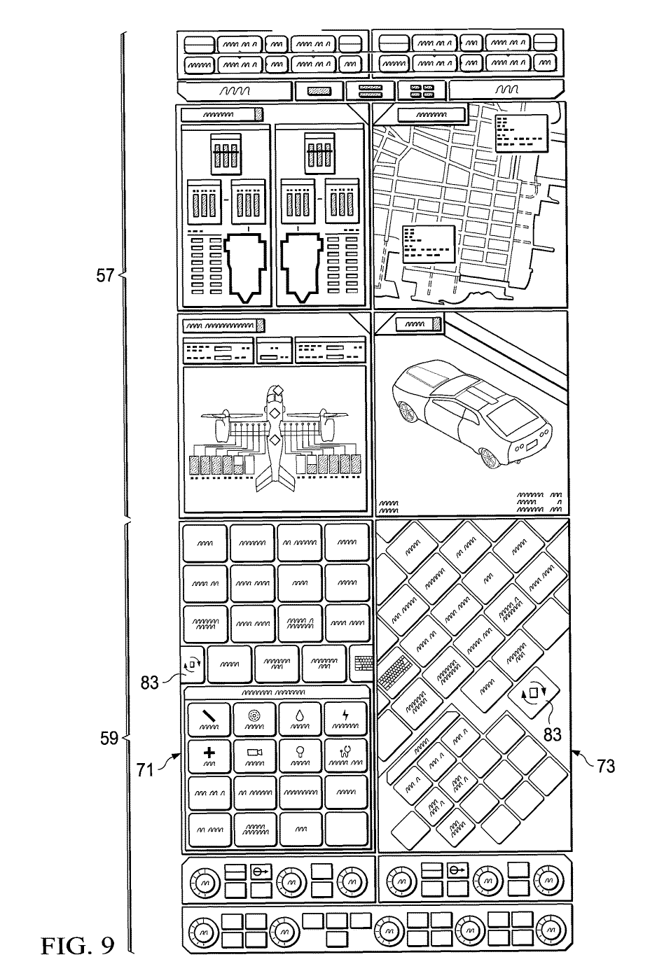

FIG. 9 illustrates another embodiment of a graphical display mode for use with interfaces 51, 53. In this display mode, the virtual input devices of section 71 are not rotated relative to the aircraft centerline, whereas those of section 73 are rotated 45 degrees. This figure highlights the differing virtual-key location configuration necessary when the virtual input device is rotated.

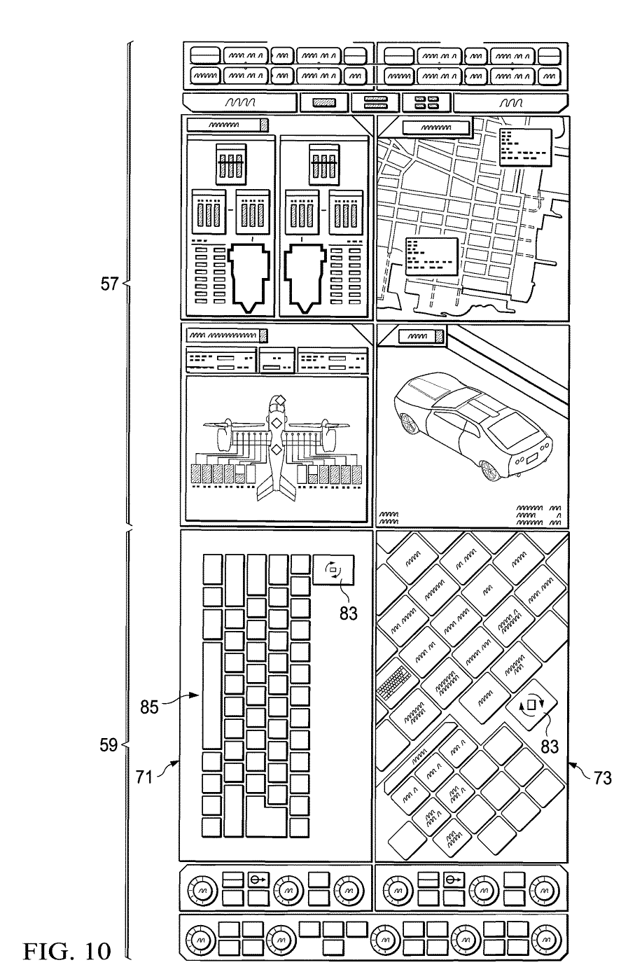

FIG. 10 illustrates another embodiment of a graphical display mode for use with interfaces 51, 53. In this display mode, the virtual input devices of section 73 are rotated 45 degrees, and a graphical representation of a full keyboard, such as QWERTY keyboard 85, is presented in section 71. Keyboard 85 is shown rotated 90 degrees relative to the aircraft centerline, which allows keyboard 85 to appear as large as possible when presented on one of sections 71, 73.

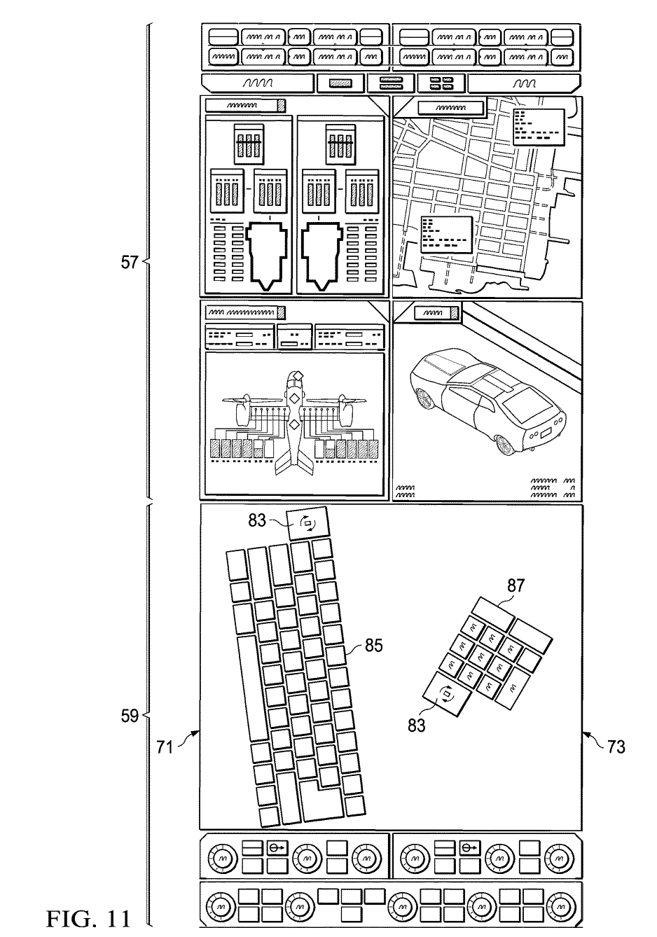

FIG. 11 illustrates another embodiment of a graphical display mode for use with interfaces 51, 53. QWERTY keyboard 85 is displayed in section 71 at an angle less than 45 degrees, and a number pad 87 is displayed in section 73 rotated at approximately 45 degrees.

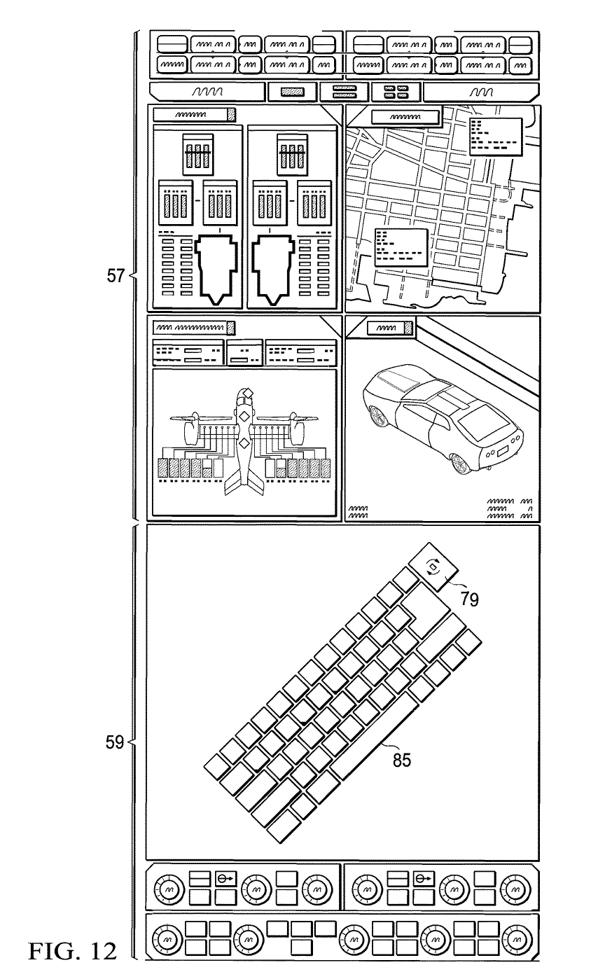

FIG. 12 illustrates another embodiment of a graphical display mode for use with interfaces 51, 53. Virtual input devices, like QWERTY keyboard 85, can be displayed across both sections 71, 73, providing for the largest possible size for the input device. As shown in the figure, QWERTY keyboard 85 is expanded to a large enough size that keyboard 85 extends into both sections 71, 73.

In addition to rotation, virtual interface elements, such as keyboard 85, number pad 87, arrays of virtual keys 79, individual virtual keys 79, virtual knobs, and other graphical representations may be moved in translation within sections 71, 73 of interface 53 or may be moved to or from another display, such as interface 51. The system will comprise instructions for detecting movement of an object, such as a finger of a crewmember or a stylus, on or near the location of a virtual interface element displayed on interface 53 and display the selected amount of translation of the selected element that corresponds to the motion of the object.

Electronic components of both panel 47 and pedestal 49 are in electronic communication with at least one general purpose processor system carried onboard aircraft 11. FIG. 13 illustrates a typical, general-purpose processor (e.g., electronic controller or computer) system 300 that includes a processing component 310 suitable for implementing one or more embodiments disclosed herein. In particular, one or more of the above-described electronic touchscreen displays may comprise one or more systems 300. In addition to the processor 310 (which may be referred to as a central processor unit or CPU), the system 300 might include network connectivity devices 320, random access memory (RAM) 330, read only memory (ROM) 340, secondary storage 350, and input/output (I/O) devices 360. In some cases, some of these components may not be present or may be combined in various combinations with one another or with other components not shown. These components might be located in a single physical entity or in more than one physical entity. Any actions described herein as being taken by the processor 310 might be taken by the processor 310 alone or by the processor 310 in conjunction with one or more components shown or not shown in the drawing. It will be appreciated that the data described herein can be stored in memory and/or in one or more databases.

The processor 310 executes instructions, codes, computer programs, or scripts that it might access from the network connectivity devices 320, RAM 330, ROM 340, or secondary storage 350 (which might include various disk-based systems such as hard disk, floppy disk, optical disk, or other drive). While only one processor 310 is shown, multiple processors may be present. Thus, while instructions may be discussed as being executed by a processor, the instructions may be executed simultaneously, serially, or otherwise by one or multiple processors. The processor 310 may be implemented as one or more CPU chips.

The network connectivity devices 320 may take the form of modems, modem banks, Ethernet devices, universal serial bus (USB) interface devices, serial interfaces, token ring devices, fiber distributed data interface (FDDI) devices, wireless local area network (WLAN) devices, radio transceiver devices such as code division multiple access (CDMA) devices, global system for mobile communications (GSM) radio transceiver devices, worldwide interoperability for microwave access (WiMAX) devices, and/or other well-known devices for connecting to networks. These network connectivity devices 320 may enable the processor 310 to communicate with the Internet or one or more telecommunications networks or other networks from which the processor 310 might receive information or to which the processor 310 might output information.

The network connectivity devices 320 might also include one or more transceiver components 325 capable of transmitting and/or receiving data wirelessly in the form of electromagnetic waves, such as radio frequency signals or microwave frequency signals. Alternatively, the data may propagate in or on the surface of electrical conductors, in coaxial cables, in waveguides, in optical media such as optical fiber, or in other media. The transceiver component 325 might include separate receiving and transmitting units or a single transceiver. Information transmitted or received by the transceiver 325 may include data that has been processed by the processor 310 or instructions that are to be executed by processor 310. Such information may be received from and outputted to a network in the form, for example, of a computer data baseband signal or signal embodied in a carrier wave. The data may be ordered according to different sequences as may be desirable for either processing or generating the data or transmitting or receiving the data. The baseband signal, the signal embedded in the carrier wave, or other types of signals currently used or hereafter developed may be referred to as the transmission medium and may be generated according to several methods well known to one skilled in the art.

The RAM 330 might be used to store volatile data and perhaps to store instructions that are executed by the processor 310. The ROM 340 is a non-volatile memory device that typically has a smaller memory capacity than the memory capacity of the secondary storage 350. ROM 340 might be used to store instructions and perhaps data that are read during execution of the instructions. Access to both RAM 330 and ROM 340 is typically faster than to secondary storage 350. The secondary storage 350 is typically comprised of one or more disk drives or tape drives and might be used for non-volatile storage of data or as an over-flow data storage device if RAM 330 is not large enough to hold all working data. Secondary storage 350 may be used to store programs or instructions that are loaded into RAM 330 when such programs are selected for execution or information is needed.

The I/O devices 360 may include liquid crystal displays (LCDs), touchscreen displays, keyboards, keypads, switches, dials, mice, track balls, voice recognizers, card readers, paper tape readers, printers, video monitors, transducers, sensors, or other well-known input or output devices. Also, the transceiver 325 might be considered to be a component of the I/O devices 360 instead of or in addition to being a component of the network connectivity devices 320. Some or all of the I/O devices 360 may be substantially similar to various components disclosed herein.

While the embodiments are shown and described in use with an aircraft, the apparatus, systems, and methods of this disclosure are equally applicable to other vehicle types, including those found in automotive and marine applications.

At least one embodiment is disclosed and variations, combinations, and/or modifications of the embodiment(s) and/or features of the embodiment(s) made by a person having ordinary skill in the art are within the scope of the disclosure. Alternative embodiments that result from combining, integrating, and/or omitting features of the embodiment(s) are also within the scope of the disclosure. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, Rₗ, and an upper limit, Rᵤ, is disclosed, any number falling within the range is specifically disclosed. In particular, the following numbers within the range are specifically disclosed: R=Rₗ+k*(Rᵤ−Rₗ), wherein k is a variable ranging from 1 percent to 100 percent with a 1 percent increment, i.e., k is 1 percent, 2 percent, 3 percent, 4 percent, 5 percent, . . . 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of the term “optionally” with respect to any element of a claim means that the element is required, or alternatively, the element is not required, both alternatives being within the scope of the claim. Use of broader terms such as comprises, includes, and having should be understood to provide support for narrower terms such as consisting of, consisting essentially of, and comprised substantially of. Accordingly, the scope of protection is not limited by the description set out above but is defined by the claims that follow, that scope including all equivalents of the subject matter of the claims. Each and every claim is incorporated as further disclosure into the specification and the claims are embodiment(s) of the present invention.

What is claimed is:

1. An aircraft system interface, comprising:
a center pedestal;
a first touchscreen display carried by the center pedestal;
one or more processors;
memory; and
one or more programs, wherein the one or more programs are stored in the memory and configured to be executed by the one or more processors, the programs including:
instructions for displaying a virtual input device on the first touchscreen display;
instructions for detecting a movement of an object on or near the first touchscreen display; and
instructions for rotating the virtual input device displayed on the first touchscreen display in response to detecting the movement.

2. The aircraft system interface of claim 1, wherein the virtual input device is a keyboard.

3. The aircraft system interface of claim 1, wherein the virtual input device is a number pad.

4. The aircraft system interface of claim 1, wherein the virtual input device is an array of virtual keys.

5. The aircraft system interface of claim 1, the programs further comprising:
instructions for displaying a rotate button on the first touchscreen display, movement of the object on or near the rotate button causing a preselected rotation of the virtual input device.

6. The aircraft system interface of claim 1, the programs further comprising:
instructions for displaying a rotate button on the first touchscreen display, movement of the object on or near the rotate button causing an amount rotation of the virtual input device corresponding to the amount of movement of the object.

7. The aircraft system interface of claim 1, the programs further comprising:
instructions for displaying different virtual input devices on adjacent sections of the first touchscreen display.

8. The aircraft system interface of claim 1, the programs further comprising:
instructions for displaying different virtual input devices on adjacent sections of the first touchscreen display; and
instructions for displaying a rotate button on the first touchscreen display, movement of the object on or near the rotate button causing a rotation of the virtual input device;
wherein each virtual input devices can be individually rotated to a selected angle.

9. The aircraft system interface of claim 1, the programs further comprising:
instructions for displaying a virtual input device across adjacent sections of the first touchscreen display.

10. The aircraft system interface of claim 1, the programs further comprising:
instructions for allowing movement of the object on or near the virtual input device to cause translation motion of the virtual input device on the first touchscreen display.

11. The aircraft system interface of claim 1, the programs further comprising:
instructions for allowing movement of the object on or near the virtual input device to cause translation motion of the virtual input device on the first touchscreen display.

12. The aircraft system interface of claim 1, further comprising:
a second touchscreen display;
instructions for allowing movement of the object on or near the virtual input device to cause translation motion of the virtual input device between the first touchscreen display and the second touchscreen display.

13. An aircraft, comprising:
a cockpit;
a center pedestal located within the cockpit;
a touchscreen display carried by the center pedestal;
one or more processors;
memory; and
one or more programs, wherein the one or more programs are stored in the memory and configured to be executed by the one or more processors, the programs including:
instructions for displaying a virtual input device on the touchscreen display;
instructions for detecting a movement of an object on or near the touchscreen display; and
instructions for rotating the virtual input device displayed on the touchscreen display in response to detecting the movement.

14. The aircraft of claim 13, wherein the virtual input device is a keyboard.

15. The aircraft of claim 13, wherein the virtual input device is a number pad.

16. The aircraft of claim 13, wherein the virtual input device is an array of virtual keys.

17. The aircraft of claim 13, the programs further comprising:
instructions for displaying a rotate button on the touchscreen display, movement of the object on or near the rotate button causing a preselected rotation of the virtual input device.

18. The aircraft of claim 13, the programs further comprising:
instructions for displaying a rotate button on the touchscreen display, movement of the object on or near the rotate button causing an amount rotation of the virtual input device corresponding to the amount of movement of the object.

19. The aircraft of claim 13, further comprising:
a second touchscreen display;
instructions for allowing movement of the object on or near the virtual input device to cause displayed translation motion of the virtual input device between the first touchscreen display and the second touchscreen display.

20. A method of displaying a virtual input device in an aircraft; the method comprising:
(a) displaying a virtual input device on a touchscreen display on a center pedestal in a cockpit;
(b) displaying a virtual rotate button on the touchscreen display; and
(c) rotating the virtual input device in response to movement of an object on or near the virtual rotate button.
